(19) United States
(12) Patent Application Publication
(10) Pub. No.: US 2007/0105239 A1
(43) Pub. Date: May 10, 2007

(54) METHOD OF FORMING VERTICAL MICROELECTRODES IN A MICROCHANNEL

(75) Inventors: Abraham P. Lee, Irvine, CA (US); Lisen Wang, Irvine, CA (US)

Correspondence Address: Vista IP Law Group LLP, 2040 MAIN STREET, 9TH FLOOR, IRVINE, CA, 92614, US

(73) Assignee: THE REGENTS OF THE UNIVERSITY OF CALIFORNIA, Oakland, CA (US)

(21) Appl. No.: 11/557,060

(22) Filed: Nov. 6, 2006

Related U.S. Application Data
(60) Provisional application No. 60/734,544, filed on Nov. 7, 2005.

(51) Int. Cl. H01L 21/00

(52) U.S. Cl. 438/1

(57) ABSTRACT

A method for forming vertical electrodes in a microchannel includes providing a substrate having a cross-linked polymer layer thereon. A plurality of electrical contacts are then patterned on the cross-linked polymer. A photoresist is applied on the cross-linked polymer overtop the electrical contacts. Holes or vias are formed in the photoresist and a metallic material is deposited therein to form vertically-oriented electrodes. Optionally, the electrodes may be coated with a biocompatible metal such as platinum. The remaining photoresist on the cross-linked polymer is then removed. An epoxy-based photoresist such as SU-8 is applied over the substrate and portions of the photoresist are lithographically exposed and removed to form the microchannel. The vertical electrodes may be located on opposing sides of the microchannel. Finally, the microchannel is sealed a cap.

### REFERENCE TO RELATED APPLICATIONS

This Application claims priority to U.S. Provisional Patent Application No. 60/734,544 filed on Nov. 7, 2005. U.S. Provisional Patent Application No. 60/734,544 is incorporated by reference as if set forth fully herein.

### FIELD OF THE INVENTION

The field of the invention generally relates to methods and processes for creating vertical microelectrodes inside a polymer microchannel. More particularly, the field of the invention relates to micro-fabrication processes used to fabricate microchannels with embedded microelectrodes for electrical manipulation of chemical or biological objects. The process enables vertical electrodes to be made along the height of the microchannel. This configuration enables the integration of multifunctional devices on a single chip or substrate.

### BACKGROUND OF THE INVENTION

Microfluidic-based systems are widely used in biological and chemical analysis applications. SU-8, for example, is an epoxy-based photoresist that is widely used in microfluidic applications for making molds for the construction of microchannels. Most of the current fabrication of SU-8-based channels is combined with other materials to make hybrid microchannels. This results in channels with inhomogeneous surface properties. The differential surface properties is, however, a serious limitation for various biochemistry applications.

For microfluidic applications, different electrodes may sometimes be positioned within the microfluidic channels, The electrodes may be patterned by metal evaporation methods such as thermal evaporation, electric beam evaporation, and sputtering. Because most of the deposition methods only deposit very thin layers of metal (e.g., usually on the order of thousands of Angstroms), this poses unique problems to their formation within microfluidic channels. This is because microfluidic channels are very small (have dimensions of 10-100 μm), and the deposited electrodes are typically deposited (e.g., formed) at the bottom of the microchannel. Unfortunately, electrodes deposited at the bottom of the microchannel create a non-uniform electric field distribution. This kind of configuration is widely used for electric manipulation such as dielectrophoresis for separation and electrowetting. In some cases, however, there is a need for uniform electric fields to achieve the desired performance.

In addition, surface-based electrodes generate electric fields that decay fast along the direction of the height of the channel. Consequently, only objects close to the bottom of the channel can be affected by the electric field. There thus is a need for electrodes that can create uniform electric fields within a microchannel.

### SUMMARY

In one embodiment of the invention, a method of forming vertical electrodes in a microchannel includes providing a substrate having a cross-linked polymer layer thereon. A plurality of electrical contacts are patterned on the cross-linked polymer. A photoresist is applied on the cross-linked polymer and overtop the electrical contacts. Holes or vias are formed in the photoresist and metallic material is deposited within the holes or vias to form the vertically-oriented electrodes. The electrodes may be formed by electrodeposition of a metal, for example, gold, inside the holes or vias. The deposition rate is controlled to produce smooth surfaced electrodes. Generally, a lower deposition rate produces smoother electrodes. The remaining photoresist is removed from the device. Next, an epoxy-based photoresist like SU-8 applied over the substrate and a channel is patterned via lithographic methods. For example, the photoresist is exposed to light using a mask and the areas where the microchannels are formed are developed with a developer solution to form the microchannel(s). In one aspect, the vertical electrodes are formed on opposing sides of the microchannel. The open side (e.g., top side) of the microchannel is then capped with a capping member such as a sheet of PDMS.

In another embodiment of the invention, a method for forming vertical electrodes microchannels includes the steps of providing a substrate and forming a layer of photoresist on the substrate. The photoresist is exposed to a cross-linking radiation source such as UV light. A seed layer is then patterned on the cross-linked photoresist layer to form electrode contact pads and traces or electrical lines that connect with the vertically-oriented electrodes. A photoresist is then patterned on the patterned seed layer and holes or vias are created using lithographic techniques in those areas where the electrodes are desired. Metal is then plated in the holes or vias to form the vertically-oriented electrodes. The metal may include, for example, gold.

The side walls of the vertical electrodes are then exposed lithographically and removed to form an access space for a subsequent capping step. With the side walls of the vertical electrodes exposed, a biocompatible metal such as platinum can be deposited thereon. For example, electrodeposition of platinum may be used. The photoresist can then be removed from the device and an epoxy-based photoresist such as SU-8 can then be coated on the device. One or more microchannels are then patterned via lithographic methods. For example, the photoresist is exposed to radiation using a mask and the areas where the microchannels are to be formed are developed with a developer solution to create the microchannel(s). The patterning is done so as to create vertically-oriented electrodes that are disposed on opposing sides of the microchannel. A cap may then be placed over the open side of the microchannel to form a sealed channel. The microchannel is preferably substantially sealed when fluid is contained, under pressure, within the confines of the microchannel.

In another aspect of the invention, a microfluidic separation device includes a first microchannel having a MHD pump formed by a pair of opposing vertically-oriented electrodes, the first microchannel terminating at a junction. A plurality of branch channels are coupled to the first microchannel via the junction, the plurality of branch channels each having at least one MHD pump formed by a pair of opposing vertically-oriented electrodes. A current or voltage source is coupled to the electrodes of each MHD pump. Each MHD pump may be independently driven to provide fluid movement in one of two directions. The various MHD pumps may be set to switch particles or cells into dedicated or pre-known branch channels based an interrogation done at the junction. For example, a detection window at the junction may be visualized using a camera or the like to identify particular cells. Based on this discrimination, the cells may be shunted to a particular branch channel for collection or subsequent processing. Other cells may be switched to a waste reservoir.

### BRIEF DESCRIPTION OF THE DRAWINGS

FIG. 1 illustrates an embodiment of a microfluidic device having a channel with vertical microelectrodes contained therein.

FIGS. 2A-2I illustrate cross-sectional views of a microfluidic device undergoing formation of vertical electrodes within a microfluidic channel.

FIGS. 3A-3J illustrate perspective views of a microfluidic device undergoing formation of vertical electrodes within a microfluidic channel.

FIGS. 4A-4H illustrate cross-sectional views of a microfluidic device undergoing formation of vertical electrodes within a microfluidic channel according to another alternative embodiment.

FIG. 5A illustrates a cross-sectional view of a microfluidic device having a inflexible glass cover for capping of the microchannel.

FIG. 5B illustrates a cross-sectional view of a microfluidic device having a flexible, polymeric cover for capping of the microchannel.

FIG. 6 illustrates a Scanning Electron Microscope (SEM) image of a cross-section of a microfluidic channel having vertically-formed electrodes. The image illustrates that the channel is sealed by the overlying SU-layer and PDMS sheet.

FIG. 7 is a schematic representation of a device used to sort cells or particles. The device includes a common microchannel and a plurality of downstream branch channels that are joined at a common junction. MHD pumps are located in each of the microchannels and can be selectively switched to direct cells or particles into specific downstream branch channels.

### DETAILED DESCRIPTION OF THE INVENTION

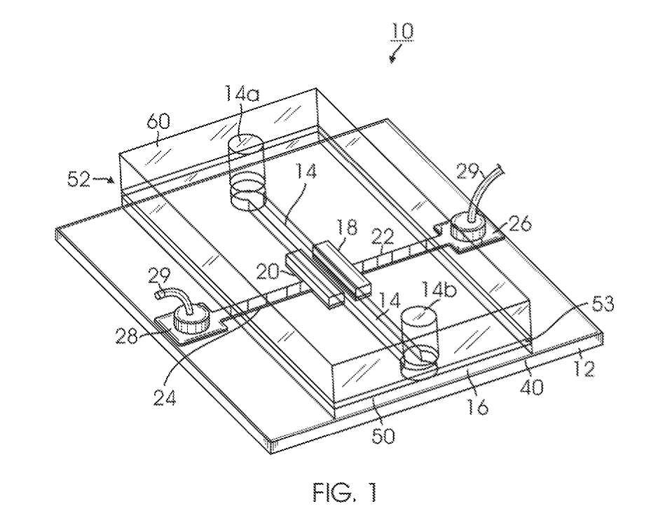

FIG. 1 illustrates a microfluidic device 10 according to one aspect of the invention. The microfluidic device 10 includes a substrate 12 onto which the device 10 is formed. The substrate 12 may include a relatively inert material such as silicon or plastic. For example, the substrate 12 may include a silicon wafer or the like. Alternatively, the substrate 12 may be formed on glass or even a plastic or polymer-based material.

A microchannel 14 is formed in a polymer-based material 16 that overlays the substrate 12. The polymer-based material 16 may include a photoresist such as, for instance, SU-8. As seen in FIG. 1, the microchannel 14 has a length that terminates in two ends 14a, 14b. One end (e.g., 14a) may be used as an inlet and the other end (i.e., 14b) may be used as the outlet. Of course, the microchannel 14 illustrated in FIG. 1 is for exemplary purposes. Much more complicated structures having junctions, separation areas, mixing regions, and like may be employed in connection with invention.

Still referring to FIG. 1, the opposing vertically-oriented electrodes 18, 20 are disposed on opposite sides of the microchannel 14. The vertically-oriented electrodes 18, 20 are formed from an electrically-conductive material such as, for instance, gold. Generally, it is preferable to form the vertically-oriented electrodes 18, 20 with smooth surfaces so as to create a uniform electrical field. If the electrodes 18, 20 have a rough surface, this tends to contribute to local electric field non-uniformity. The surface roughness of the electrodes 18, 20 may be controlled, in part, by the rate at which the metallic species is deposited (e.g., electroplated). Each electrode 18, 20 is coupled to respective electrical traces or lines 22, 24. The electrical traces or lines 22, 24 may be formed from an electrically-conductive material such as, for instance, gold. As seen in FIG. 1, each electrical trace or line 22, 24 terminates in an electrical contact or pad 26, 28. The electrical contact 26, 28 for each electrode 18, 20 may then be connected to a voltage or current source (not shown) via leads 29.

FIG. 1 illustrates a pair of opposing vertical electrodes 18, 20 with each terminating in respective electrical contacts 26, 28. In other embodiments, a plurality of pairs of electrodes 18, 20 may be positioned along the length of the microchannel 14. Each pair of electrodes 18, 20 along the length of the microchannel 14 can terminate at their own respective contacts 26, 28. Voltage switching circuitry (not shown) can then be coupled to each respective contact 26, 28 to drive the various electrodes 18, 20. The application of the electrical field between opposing electrodes 18, 20 may then be modulated to assist particles, biological, or chemical species along the length of the microchannel 14. Typically, the species, which are carried in a carrier fluid, are moved (or inhibited from movement) are charged species that interact with the electrical field created between opposing electrodes 18, 20.

Still referring to FIG. 1, a cap 60 (illustrated in outline so as to expose underlying structure) is positioned over the polymer-based material 16 in which the microchannel 14 is formed. Preferably, the polymer-based material 16 is flexible so that a good seal can be formed between the cap 60 and the underlying material 16. Of course, it may be possible to use a rigid or semi-rigid material for the cap 60. For example, glass or plastic may be used to form the cap 60.

The opposing vertical electrodes 18, 20 are located along the full height or depth of the walls forming the microchannel 14. The vertical electrodes 18, 20 generally act as two (or more as the case may be) parallel plates that provide a substantially uniform electrode field. In some embodiments, the geometry of the vertical electrodes 18, 20 may be adjusted to provide for non-uniform electrode fields in certain areas or regions of the device 10.

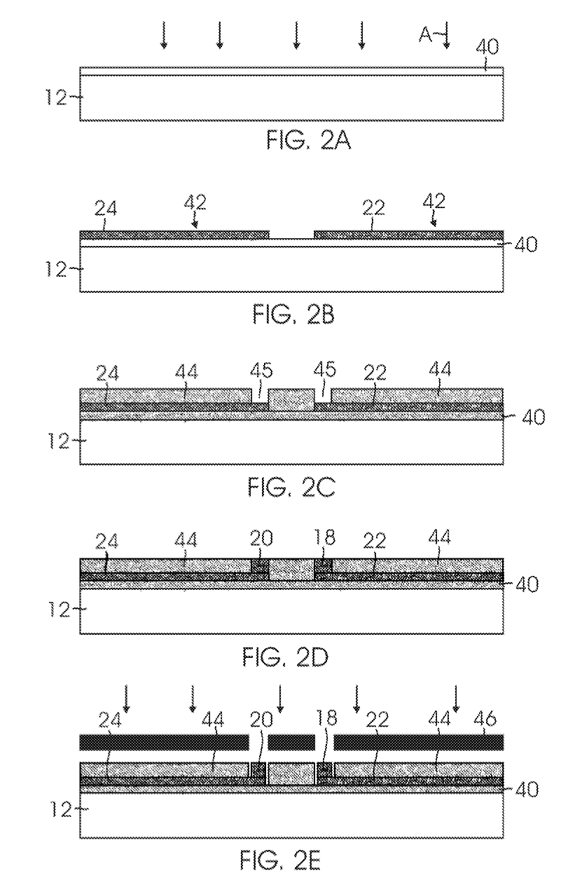

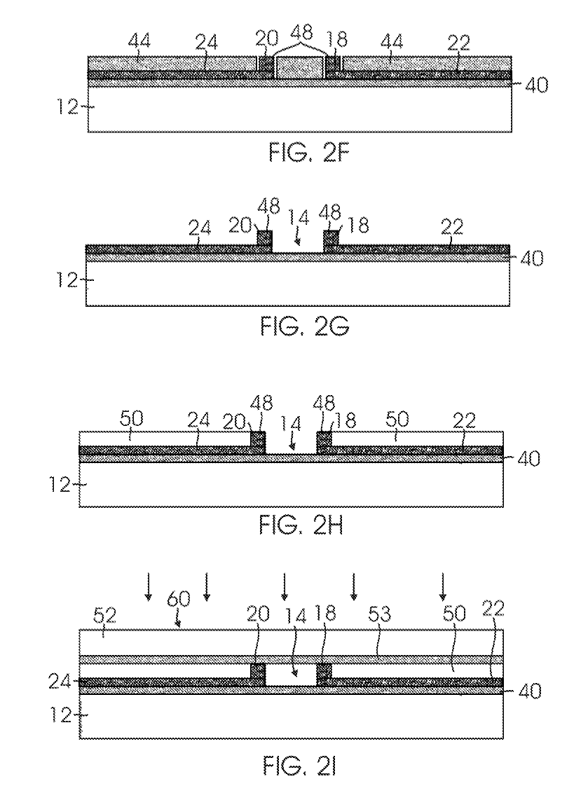

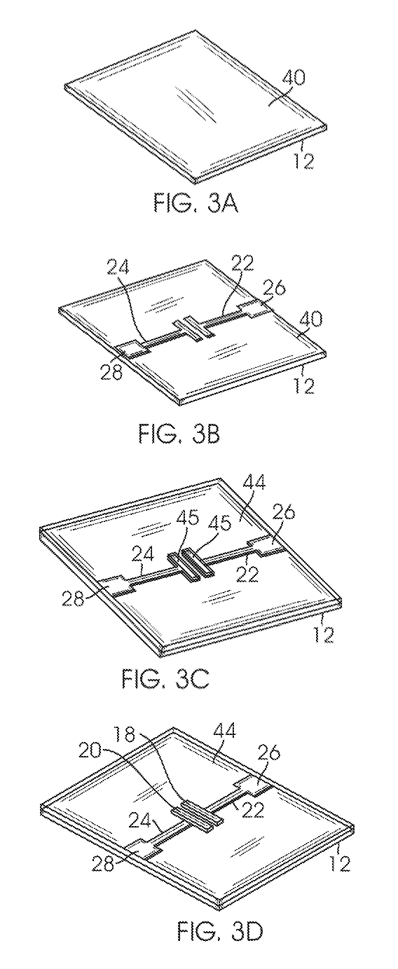

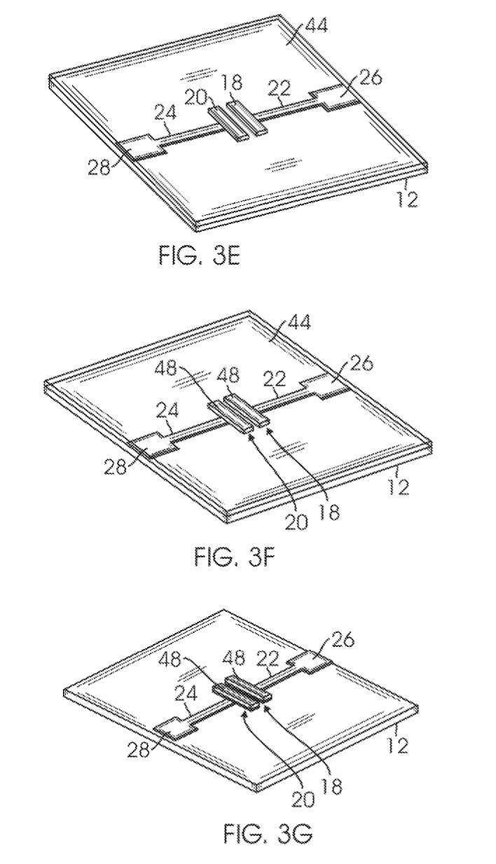

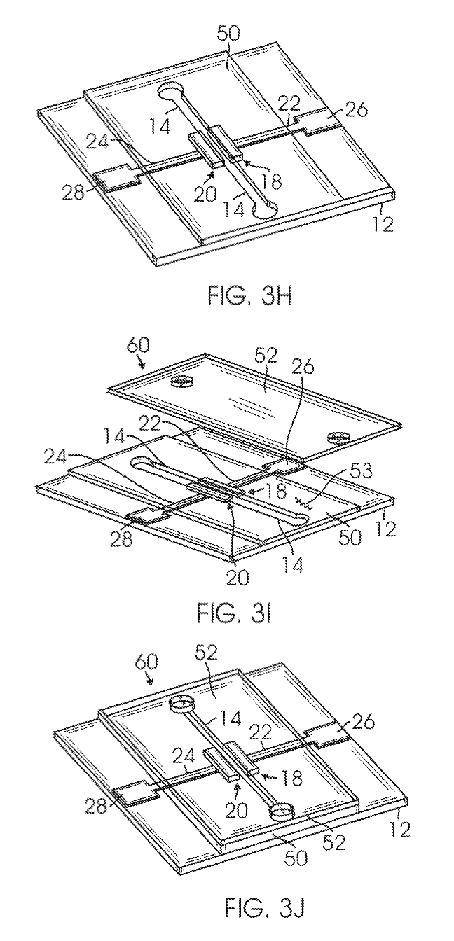

With reference to FIGS. 2A-2I and FIGS. 3A-3J, a process or method is disclosed for making the microfluidic device 10. According to one aspect of the method, the process uses a polymer-based material such as SU-8 as the channel structure. A metallic species can then be electroplated to form electrodes on the side walls of the channel structure. Additional electrodes may be formed on the bottom surface of the channel to provide for additional control.

With reference now to FIGS. 1, 2A and 3A, a substrate 12 is provided for creation of the microfluidic device 10. The substrate 12 may include, for example, silicon wafers or glass slides. For example, a substrate 12 of silicon was cleaned by standard RCA cleaning at 70° C. and the silicon wafer then was put into a 120° C. oven to dehydrate for about 20 minutes. It should be understood that the substrate 12 is used as supporting material for the overlying microfluidic device 10. While plastic substrates 12 may be used in some instances, they generally are not compatible with subsequent processing steps because of high temperatures or harsh solvents and chemicals. Nonetheless, some plastic materials may be suitable for use as the substrate 12.

As best seen in FIGS. 2A and 3A, a first thin layer of photoresist 40 (SU-8-2 Microchem Inc., MA) was spun on the silicon wafer substrate 12 at around 2000 rpm for 40 seconds, giving a thickness of around 1-2 μm. The wafer substrate 12 was then soft-baked at around 90° C. on a hotplate for 5 minutes. The wafer substrate 12 was then subject to flood ultra-violet light (UV) exposure under Karl-Suss MJB3 mask aligner to crosslink the thin layer 40 of photoresist (shown by arrows A in FIG. 2A). This was followed by a hard bake at 100° C. in an oven for 20 minutes with well leveling. The thin layer 40 of SU-8 will be the bottom layer for the microchannel 14. In addition, the thin layer 40 improves the adhesion of the channel layer 50 to the substrate 12 and serves as an insulating layer for the subsequently deposited metal layers (for electrical traces/lines 22, 24 and contacts 26, 28) when a wafer is used as the substrate 12. Although the thickness of the layer 40 is not a critical parameter, in order to achieve a substantially uniform surface profile, a thin SU-8 layer (1-2 μm) is spun instead of SU-8-10 for 8-10 μm, which gives much rougher surface profile.

Next, with reference to FIGS. 2B and 3B, the electrical traces or lines 22, 24 are patterned over the layer 40. For example, e-beam evaporation was used to grow the seed layers (200 Å titanium and 1000 Å gold) for the subsequent electroplating step. The formed metal layer 42 has strong adhesion to the SU-8 layer 40 and tape testing confirmed there is no peel-off of the metal layer 42 from the SU-8 thin layer 40, even after the metal layers 42 were patterned. The seed layer was patterned by a Shipley 1827 photoresist with a first mask used for the surface electric connection pads, leads, as well as the local patterns for growing the vertical electrodes 18, 20. The gold layer was etched by KI and I₂ gold etchant (KI:I₂:H₂O=4 g:1 g:40 g) and the titanium was removed by dipping the same into 2% hydrogen fluoride (HF). The Shipley layer was stripped by acetone followed by a rinse with methanol and de-ionized (DI) water. The device was then put into a 100° C. oven for 20 minutes of dehydration.

With reference to FIGS. 2C and 3C, a photoresist layer 44 is applied overtop the metal layer 42. Approximately 50 μm of AZ 4620 photoresist was triple-coated on the substrate 12 with 2000 rpm rotation. The substrate 12 was baked for 2 minutes on a 90° C. hotplate between each coating. Triple coating instead of a lower rpm single coating was used to reduce the non-uniformity with low rpm which will make the subsequent alignment step to be inaccurate. The edges were manually removed by a cotton tip. After twenty minutes baking at 90° C. in the oven, the AZ photoresist layer was patterned by a second mask with patterns for electroplating holes or vias 45 for the vertical electrodes 18, 20 through a mask aligner. During this process, the holes or vias 45 are defined by exposed areas of the lithographic mask. The exposed photoresist is then subject to a soft hard bake process and then developed so as to expose the holes 45. This aspect of the method is carried out using conventional lithographic methods known to those skilled in the art.

The holes 45 are formed in those locations where the electrodes 18, 20 are formed. The dose of the light intensity needs to be well controlled so that the plating mold has smooth side walls for the electroplating. For a thickness of around 50 μm, the resist layer 44 was exposed for about one minute, fifty seconds at a UV intensity of 9.6 mW/cm². The development of the photoresist was accomplished by dipping the substrate 12 into diluted AZ400k developer (DI water: AZ400K developer=4:1) solution and then the mold was hard baked at 90° C. in the oven for 20 minutes. Higher temperatures tend to make the AZ photoresist reflow and distort the patterns.

The substrate 12 and overlying layers was then dipped into a gold electroplating solution (Technics gold 25ES, Technics Inc, RD) to plate gold electrodes 18, 20 with well-controlled stir rates and current density for uniform plating (FIGS. 2D and 3D). The thickness of the plated electrodes 18, 20 was measured by an Alpha-Step 200 Surface Profilometer. The electrodes 18, 20 that were formed had heights within the range of around 40-50 μm but they may be constructed to correspond to other heights used for the microchannel 14. The rate of deposition may be controlled by modifying the electrical current applied during the deposition process. Generally, a low deposition rate produces more uniform and smoother electrodes 18, 20. The low deposition rate can be achieved by applying a lower electrical current during the deposition process. For example, experimental investigation has shown that a deposition rate of around 0.2 to 0.3 μm/min. produces a smooth surface. In addition, the plating process is controlled to underplate so as to avoid the unnecessary polishing step that would be required if the electrodes 18, 20 were overplated.

Depending on the material selection of the electrodes 18, 20, the following step is optional. For some applications, however, there is a need for more inert materials like platinum to increase the biocompatibility. In this regard, another optional thin layer of precious metal can be coated on the plated (e.g., gold) electrodes 18, 20. With reference to FIGS. 2E and 3E a mask 46 (FIG. 2E) is disposed over the substrate 12 containing the resist layer 44, and the AZ photoresist layer 44 is exposed on either side of the electrodes 18, 20. The substrate 12 is carefully aligned with the mask using a mask aligner (e.g., Karl Suss MJB3 or MA6 Mask Aligner). The AZ photoresist layer was re-patterned in this step using conventional lithographic techniques. With a second exposure of the AZ photoresist layer 44, all the side walls of the electrodes 18, 20 can be exposed (best seen in FIG. 2E). Generally, it is preferable to use a mask with a relatively high resolution (e.g., on the order of ˜1000,000 dpi). In this regard, relatively smooth electrodes 18, 20 can be created. If the film mask has a low resolution (e.g., several thousand dpi), the side wall of the mold will become very rough, thereby creating rough electrodes 18, 20.

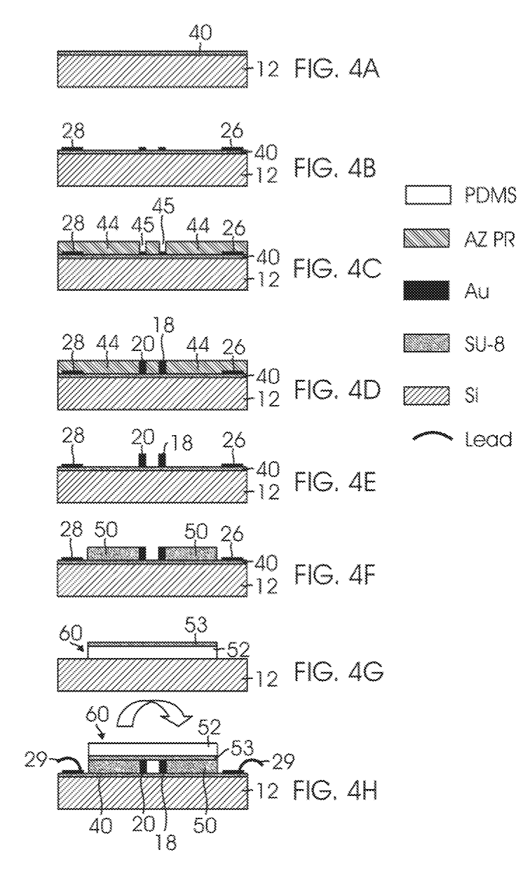

Next, as seen in FIGS. 2F and 3F, a thin capping layer (e.g., platinum) 48 was electroplated (Platinum AP, Technic Inc.) on all the surfaces of the gold electrodes 18, 20 by a second electrodeposition process. The capped, platinum electrodes 18, 20 are more inert and compatible with biological solutions. It should be understood, however, that this step is entirely optional. For example, FIGS. 4A through 4H illustrate an alternative process in which this capping step is omitted entirely. Those common features with the process of FIGS. 2A-2H and 3A-3J are labeled accordingly.

With reference to FIGS. 2G and 3G, the AZ photoresist layer 44 was stripped in an acetone solution with sonication. The substrate 12 with stand alone electrodes 18, 20 was rinsed thoroughly with DI water and then dehydrated at 120° C. in an oven for twenty minutes before coating the next SU-8 layer 50 (FIGS. 2H and 3H). With reference to FIGS. 2H and 3H, the second SU-8 layer 50 was spun onto the substrate 12 at 2000 rpm for 60 seconds and baked on a 90° C. hotplate for about ten minutes. The SU-8 layer was then subject to UV patterning to form the microchannel 42 of the device 10. At the locations within the microchannel 42 where the electrodes 18, 20 are located, the microchannel 42 is designed to be wider than the distance of the two electrodes 18, 20. In this manner, the electrodes 18, 20 were embedded within the sides of the microchannel 42 to form a substantially smooth surface within the sides of the microchannel 42.

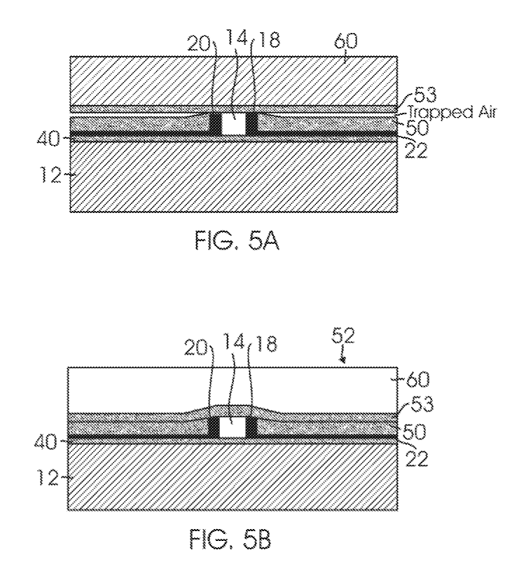

Because the vertically-oriented electrodes 18, 20 are located on the substrate 12 before coating the second SU-8 layer 50, the upper surface of the SU-8 channel layer 50 will not be perfectly flat. Consequently, this makes capping the microchannel 42 challenging if a substantially inflexible member (e.g., glass or silicon) is used to seal the microchannel 42. FIG. 5A illustrates a cross-sectional view of the device 10 having an inflexible cap 60. In order to overcome this potential problem, poly(dimethyl siloxane) (PDMS), which is a rubber-like material and has flexible mechanical properties and can bend to follow the curvature of the contact surface, may be used as the cap 60. PDMS also provides for excellent optical transparency. For example, as seen in FIGS. 2I, 3I, and 3J, a blank PDMS sheet 52 may be used to seal the microchannel 42. A relatively thick PDMS sheet 52 is preferred to impart additional rigidity so that it will not bend or flex during operation. The increased rigidity can be created using a ratio of PDMS and curing reagent with a ratio of 5:1. A typical thickness may be on the order of around 2 mm.

Unfortunately, if the microchannel 42 is directly caped with a PDMS sheet 52, because there is no bonding between the PDMS sheet 52 and the SU-8 channel layer 50, the PDMS sheet 52 will be easily peeled off by a low flow rate (e.g., 1 μL/min). To overcome this potential problem, a thin layer 53 of SU-8 may be used as “glue” to bond the photoresisist layer 50 to the PDMS sheet 52.

In order to form the PDMS sheet 52, a silicon wafer with thick SU-8 bumps was used as a mold with channel inlets and outlets. The PDMS sheet 52 was treated with oxygen plasma at 200 W RF power at 200 mT pressure for 40 seconds to make it hydrophobic. A thin layer 53 of SU-8 was then spread over the PDMS sheet 52 after baking. For example, the PDMS sheet 52 can be temporarily attached to a bare silicon wafer and a thin layer of SU-8 can be spin coated thereon. After baking the SU-8-coated PDMS sheet 52 at 90° C. hotplate for 20 minutes (to evaporate solvents), it was aligned over the microchannel 14 using a home-made micromanipulator. After alignment, the whole device 10 was placed on top of a 60° C. hotplate (four about ten minutes) and the soft PDMS conformed to the topography of the substrate channel layer 50 as shown in FIG. 5B. Some locally trapped gas can be squeezed out easily with a flat tweezer. Finally, the top PDMS/SU-8 cap 60 and channel layer 50 were UV flood-exposed again and the final device 10 was hard baked at 120° C. in an oven for 20 minutes to crosslink the thin SU-8 layer and adhere it to the channel layer 50.

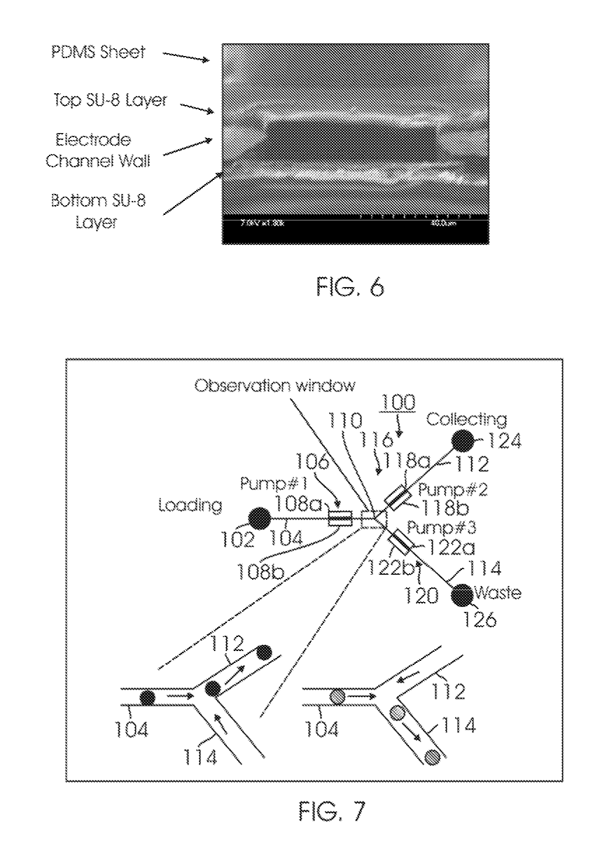

In order to investigate the sealing of the microchannel 14, the sealing was checked by visual inspection from SEM images. The cross-sectional picture of one such image is shown in FIG. 6. Pneumatic pressure was introduced into the microchannel 14 and the maximum pressure the microchannel 14 could stand was found to be around 55 psi. In addition, it was found that there are two kinds of failure modes for the broken microchannel 14. As pressure inside the channel increased higher, the bonding between the layers of SU-8 was broken and a large leak was generated. A second leakage was created in the top flexible PDMS layer 52. The top flexible layer 52 tends to deflect under the high pressure, and correspondingly the top SU-8 attached to it will also deflect. Because the SU-8 is not as flexible as the PDMS layer 52, there were cracks on the thin SU-8 top layer. While the microchannel 14 did show leakage at high pressures, the sealed microchannel 14 is able to withstand pressures typically expected to be encountered in microfluidic devices.

The device 10 may be used for any number of microfluidic applications. For example, the microfluidic device 10 may be used in a MHD (Magneto-Hydrodynamic) pump network developed to pump and sort particles or cellular matter (e.g., cells). FIG. 7 illustrates a schematic representation of a MHD sorting device 100. As seen in FIG. 7, the device 100 includes a loading zone 102 which may comprise an inlet or reservoir. The loading zone 102 is coupled to a common microfluidic channel 104 that has a first MHD pump 106. The MHD pump 106 includes a pair of vertically-oriented electrodes 108a, 108b of the type described herein. The vertically-oriented electrodes 108a, 108b are located on opposite side walls of the common microfluidic channel 104. The electrodes 108a, 108b apply a current across the channel 104 and a magnetic field is applied vertically to the channel 104 plane. The vertical electrodes 108a, 108b at the side walls will give more uniform and stronger current than planar electrode at the bottom of the channel 104.

Still referring to FIG. 7, the microfluidic channel 104 terminates a junction 110 located downstream of the first MHD pump 106. The junction 110 terminates into a plurality of branch channels 112, 114. In the embodiment of FIG. 7, the device 100 includes two such branch channels 112, 114 although additional channels (not shown) could also be employed. Each branch channel 112, 114 has its own MHD pump 116, 120. Each MHD pump 116, 120, like the prior pump 106, is formed by two opposing vertical electrodes 118a, 118b (with respect to MHD pump 116) and 122a, 122b (with respect to MHD pump 120). Each branch channel 112, 114 is collected to a particular zone or region. For example, in the configuration shown in FIG. 7, the upper branch channel 112 is connected to a collection zone 124. The collection zone 124 may include a chamber or reservoir where sorted particles or cells can accumulate. The lower branch channel 114 is terminates in waste zone 126. The waste zone 126 may include a chamber or reservoir where waste reagents and non-sorted particles or cells can accumulate.

As seen in FIG. 7, various sorting algorithms can be employed to sort particles or cells. In the algorithm on the left hand side of FIG. 7, cells or other particles of interest are sorted to the upper branch channel 112. In contrast, as seen on the right hand side of FIG. 7, waste products are shunted to the lower branch channel 114 where they can accumulate in the waste zone 126.

The MHD pumps 106, 116, 120 can generate bidirectional pumping forces. This can be achieved by controlling either the current or the electromagnetic field, or the phase difference between the two fields for alternative current (AC) MHD pumps. The device 100 in FIG. 7 utilizes this property of MHD pumps for sorting of cells or particles. Since on-chip MHD pumps can immediately change the flow pattern by switching the local electrical fields within the microchannels 104, 112, 114, this instant switching is critical for high purity cell sorting. In this platform, the microchannels 104, 112, 114 can be made small enough to allow only single cell (or particle) to pass through. As shown in FIG. 7, MHD pump 106 at the upstream location of the channel junction 110 pumps different cells into the common channel 104. At different times, different cells pass the junction where an observation is recorded by a digital camera and computer (not shown). When the cells are of the first type (algorithm on the left hand side of FIG. 7), the MHD pump 116 in the upper branch channel 112 is activated towards the right and the MHD pump 120 in the lower branch channel 114 is activated towards the left which will function as a valve to prevent fluid from flowing into the lower branch channel 114. As a result, the cells will be deflected to the top branch channel 112. When another type of cell (algorithm on right hand side of FIG. 7) comes, the MHD pumps 116, 120 can be reversed in flow directions and the cells can be deflected to the lower branch channel 114.

Multiple outlet branches with MHD pumps (i.e., beyond the two in FIG. 7) can be integrated if more cells types need to be sorted. In this embodiment, MHD pumps located downstream will be adjusted to direct the cells to the appropriate outlet channel. Referring back to FIG. 7, during the sorting process, target cells are collected in the top collection zone 124 and others are directed to the waste zone 126 for disposal.

The successful pumping and switching of B103 cells in PBS cellular medium has been successfully demonstrated using a MHD device 100 of the type described herein. The same switching process has also been demonstrated with the mouse neural stem cells in L15 media. The switching can be immediately realized when the cell is detected within the observation window at the junction 110.

The successful pumping of cells and the associated cell media depends on the electrical conductivity of the media that is used. Because the electrodes 108a, 108b, 118a, 118b, 122a, 122b are directly in contact with the flow in the channels 104, 112, 114, when a high voltage is applied that exceeds the over-potential for water undergoing electrolysis, the bubbles generated from the electrochemical reaction will block the channel and therefore prevent the MHD pumps from working efficiently. Proper selection of a cell medium with high conductivity is important for the MHD pumping and correspondingly, the sorting of the cells. Table 1 below shows the comparison of seven different cell media's conductivity and threshold currents for bubble generation in the channel.

TABLE 1

| Media | Conductivity (mS/cm) |
|---|---|
| DMEM-F12 | 11.79 |
| SMEM-F12 with 10% serum | 13.78 |
| DMEM-F12 with serum-free | 14.11 |
| supplements | |
| DMEM-F12 with 1% serum | 14.12 |
| EMEM | 14.78 |
| Phosphate Buffer Solution (PBS) | 15.01 |
| L15 (Leibowitz) | 15.18 |

As can be seen from Table 1, the higher conductivity the medium is, the higher threshold current can be applied across the electrodes. In order for MHD pumps 106, 116, 120 to work effectively, the current applied needs to be as high as possible (neglecting the Joule heating effect). PBS has a high threshold current and good conductivity parameters for MHD pumping but it may not be compatible with all cell types (such as mouse NSCs). Therefore, the media choice has to balance conductivity as well as cell viability. L15 has an even higher conductivity than PBS and is a commonly used CO₂-independent media. Consequently, it is a good candidate for MHD pumping applications.

It should be understood that the vertical electrodes described herein may be used in applications other than MHD. For example, the vertical electrodes may be utilized in dielectrophoresis (DEP), isoelectricfocusing, electrical or electrochemical sensing, electroporation and other microfluidic applications that use an electric field to manipulate flow or objects in a fluid. As one illustrative example, vertically-oriented electrodes positioned at the side wall of a microchannel may be used to generate non-uniform electrical fields for applications such as DEP.

While embodiments of the present invention have been shown and described, various modifications may be made without departing from the scope of the present invention. The invention, therefore, should not be limited, except to the following claims, and their equivalents.

What is claimed is:

1. A method for forming vertical electrodes in a microchannel comprising:
providing a substrate having a cross-linked polymer layer thereon;
patterning a plurality of electrical contacts on the cross-linked polymer;
applying a photoresist on the cross-linked polymer and overtop the electrical contacts;
forming holes in the photoresist and depositing a metallic material in the holes to form vertical electrodes;
removing the remaining photoresist on the cross-linked polymer;
applying an epoxy-based photoresist over the substrate and removing the portion between the vertical electrodes to form the microchannel; and
sealing the microchannel with a cap.

2. The method of claim 1, wherein the substrate comprises glass.

3. The method of claim 1, wherein the substrate comprises silicon.

4. The method of claim 1, wherein the metallic material comprises gold.

5. The method of claim 4, further comprising the step of capping a surface of the gold electrodes with platinum.

6. The method of claim 1, wherein the cap comprises a sheet of PDMS.

7. The method of claim 1, wherein the photoresist comprises SU-8.

8. The method of claim 1, wherein the electrodes are disposed on opposing sides of the microchannel.

9. A microfluidic device produced by the method of claim 1.

10. A method for forming vertical electrodes in microchannels comprising:
(a) providing a substrate;
(b) forming a layer of photoresist on the substrate;
(c) exposing the photoresist on the substrate to UV radiation;
(d) patterning a seed layer on the photoresist to form localized patterns for electrode connections;
(e) coating a photoresist on the patterned seed layer and patterning holes for the vertical electrodes;
(f) plating metallic vertical electrodes within the electroplating holes;
(g) exposing the side walls of the vertical electrodes and capping the side walls with platinum;
(h) removing the photoresist formed in step (e);
(i) coating the substrate with photoresist and forming a microchannel, wherein the vertical electrodes are formed on opposing sides of the microchannel; and
(j) forming a cap over the microchannel.

11. The method of claim 10, further comprising the step of depositing a platinum layer on the metallic vertical electrodes formed in step (f).

12. The method of claim 10, wherein the cap comprises a sheet of PDMS.

13. The method of claim 10, wherein the photoresist comprises SU-8.

14. The method of claim 10, wherein the cap is secured to the coated substrate with an adhesive.

15. A microfluidic device produced by the method of claim 10.

16. A microfluidic separation device comprising:
a first microchannel having a MHD pump formed by a pair of opposing vertically-oriented electrodes, the first microchannel terminating at a junction;
a plurality of branch channels coupled the first microchannel via the junction, the plurality of branch channels each having at least one MHD pump formed by a pair of opposing vertically-oriented electrodes; and
a current source coupled to the electrodes of each MHD pump, each MHD pump being independently driven of one another.

17. The microfluidic separation device of claim 16, wherein the microchannel is formed within an epoxy-based photoresist.

18. The microfluidic separation device wherein at least one of the branch channels terminates in a collection reservoir.

19. The microfluidic separation device wherein at least one of the branch channels terminates in a waste reservoir.

20. The microfluidic separation device wherein the first microchannel and the plurality of branch channels are dimensioned to permit passage of a single cell.
